(19) United States
(12) Patent Application Publication
(10) Pub. No.: US 2019/0123778 A1
(43) Pub. Date: Apr. 25, 2019

(54) MONOLITHIC MICROWAVE INTEGRATED CIRCUIT (MMIC) FOR PHASED ARRAY ANTENNA SYSTEM AND PHASED ARRAY ANTENNA SYSTEM INCLUDING THE SAME

(71) Applicant: Electronics and Telecommunications Research Institute, Daejeon (KR)

(72) Inventors: Jin Cheol JEONG, Daejeon (KR); Dong Hwan SHIN, Daejeon (KR); Man Seok UHM, Daejeon (KR); IN BOK YOM, Daejeon (KR)

(73) Assignee: Electronics and Telecommunications Research Instit ute, Daejeon (KR)

(21) Appl. No.: 15/896,809

(22) Filed: Feb. 14, 2018

(30) Foreign Application Priority Data
Oct. 20, 2017 (KR) 10-2017-0136698

(51) Int. Cl. H04B 1/44; H01Q 1/22; H01Q 23/00; H01Q 21/06; H03F 3/195; H03F 3/213

(52) U.S. Cl. CPC H04B 1/44; H01Q 1/2283; H01Q 23/00; H03F 2200/451; H03F 3/195; H03F 3/213; H01Q 21/06

(57) ABSTRACT

A monolithic microwave integrated circuit (MIMIC) for a phased array antenna system, and a phased array antenna system including the MIMIC are provided. The MIMIC includes a first amplifier including a first input terminal and a first output terminal, a second amplifier including a second input terminal and a second output terminal, a first switch connectable to the first input terminal and the second output terminal, and a second switch connectable to the first output terminal and the second input terminal.

### CROSS-REFERENCE TO RELATED APPLICATION

This application claims the benefit of Korean Patent Application No. 10-2017-0136698, filed on Oct. 20, 2017, in the Korean Intellectual Property Office, the disclosure of which is incorporated herein by reference.

### BACKGROUND

### 1. Field of the Invention

One or more example embodiments relate to a monolithic microwave integrated circuit (MIMIC) for a phased array antenna system, and a phased array antenna system including the MMIC.

### 2. Description of the Related Art

Multi-function monolithic microwave integrated circuits (MMICs) provide a function of controlling a signal attenuation and a phase shift for each array of array antennas.

A multi-function integrated circuit (IC) used in a pulse mode radar is synchronized with an input pulse signal and operates in a reception (Rx) mode and a transmission (Tx) mode.

In a phased array radar system, an Rx mode input and a Tx mode output of a multi-function MIMIC are connected to an antenna, and accordingly signals in the Rx mode and the Tx mode move in opposite directions.

A method of bidirectionally propagating signals for the same circuit may be performed when the circuit is a passive circuit. A 2-port passive circuit has similar characteristics even though an input and an output are exchanged with each other. For example, a digital phase shifter and a digital attenuator that are passive circuits are used to enable a bidirectional signal movement for an Rx mode and a Tx mode. The above passive circuits have a disadvantage in that a noise factor characteristic deteriorates in the Rx mode and that an output power characteristic deteriorates in the Tx mode due to a great attenuation of a signal.

### SUMMARY

Example embodiments provide a technology that is excellent in an output power characteristic in a transmission (Tx) mode and a noise factor characteristic in a reception (Rx) mode, by connecting a switch to an input and an output of each of an input amplifier and an output amplifier arranged in parallel in different directions, that consumes a small amount of direct current (DC) power, and that does not have a possibility of an occurrence of a loop resonance.

According to an aspect, there is provided a monolithic microwave integrated circuit (MIMIC) for a phased array antenna system, the MIMIC including a first amplifier including a first input terminal and a first output terminal, a second amplifier including a second input terminal and a second output terminal, a first switch connectable to the first input terminal and the second output terminal, and a second switch connectable to the first output terminal and the second input terminal.

The first amplifier and the second amplifier may be arranged in parallel in opposite directions and may be located between the first switch and the second switch.

The MMIC may further include a serial-to-parallel converter (SPC) configured to control the MMIC.

The SPC may be configured to control a signal to be transmitted through one of the first amplifier and the second amplifier in each of an Rx mode and a Tx mode of the MMIC.

The SPC may be configured to control a DC bias to be prevented from being supplied to the other one of the first amplifier and the second amplifier in each of the Rx mode and the Tx mode.

The first switch and the second switch may operate to connect the first input terminal and the first output terminal to an element of the MIMIC in the Rx mode, and may operate to connect the second input terminal and the second output terminal to the element of the MMIC in the Tx mode.

The first amplifier may be turned on in the Rx mode and turned off in the Tx mode.

The second amplifier may be turned off in the Rx mode and turned on in the Tx mode.

The first amplifier and the second amplifier may be implemented as enhancement-mode high electron mobility transistor (E-HEMT)-based amplifiers.

According to another aspect, there is provided a phased array antenna system including a phased array antenna, and an MMIC that is configured to control the phased array antenna.

The MMIC may include a first amplifier including a first input terminal and a first output terminal, a second amplifier including a second input terminal and a second output terminal, a first switch connectable to the first input terminal and the second output terminal, and a second switch connectable to the first output terminal and the second input terminal.

The first amplifier and the second amplifier may be arranged in parallel in opposite directions and may be located between the first switch and the second switch.

The MMIC may further include an SPC configured to control the MMIC.

The SPC may be configured to control a signal to be transmitted through one of the first amplifier and the second amplifier in each of an Rx mode and a Tx mode of the MMIC.

The SPC may be configured to control a DC bias to be prevented from being supplied to the other one of the first amplifier and the second amplifier in each of the Rx mode and the Tx mode.

The first switch and the second switch may operate to connect the first input terminal and the first output terminal to an element of the MIMIC in the Rx mode, and may operate to connect the second input terminal and the second output terminal to the element of the MMIC in the Tx mode.

The first amplifier may be turned on in the Rx mode and turned off in the Tx mode. The second amplifier may be turned off in the Rx mode and turned on in the Tx mode.

The first amplifier and the second amplifier may be implemented as E-HEMT-based amplifiers.

Additional aspects of example embodiments will be set forth in part in the description which follows and, in part, will be apparent from the description, or may be learned by practice of the disclosure.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a diagram illustrating an example of a structure of a multi-function monolithic microwave integrated circuit (MMIC) according to a related art;

FIG. 2 is a diagram illustrating another example of a structure of a multi-function MMIC according to a related art;

FIG. 3 is a diagram illustrating a structure of a multi-function MIMIC according to an example embodiment;

FIG. 4 is a diagram illustrating a circuit for an operation of switches located in front of and behind two amplifiers that are located in opposite directions; and

FIG. 5 is a diagram illustrating a structure of a phased array antenna system according to an example embodiment.

### DETAILED DESCRIPTION

The following structural or functional descriptions of example embodiments described herein are merely intended for the purpose of describing the example embodiments described herein and may be implemented in various forms. However, it should be understood that these example embodiments are not construed as limited to the illustrated forms.

Various modifications may be made to the example embodiments. Here, the examples are not construed as limited to the disclosure and should be understood to include all changes, equivalents, and replacements within the idea and the technical scope of the disclosure.

Although terms of “first,” “second,” and the like are used to explain various components, the components are not limited to such terms. These terms are used only to distinguish one component from another component. For example, a first component may be referred to as a second component, or similarly, the second component may be referred to as the first component within the scope of the present disclosure.

When it is mentioned that one component is “connected” or “accessed” to another component, it may be understood that the one component is directly connected or accessed to another component or that still other component is interposed between the two components. In addition, it should be noted that if it is described in the specification that one component is “directly connected” or “directly joined” to another component, still other component may not be present therebetween. Likewise, expressions, for example, “between” and “immediately between” and “adjacent to” and “immediately adjacent to” may also be construed as described in the foregoing.

The terminology used herein is for the purpose of describing particular embodiments only and is not intended to be limiting. As used herein, the singular forms are intended to include the plural forms as well, unless the context clearly indicates otherwise. It will be further understood that the terms “comprises” and/or “comprising,” when used in this specification, specify the presence of stated features, integers, steps, operations, elements, components or a combination thereof, but do not preclude the presence or addition of one or more other features, integers, steps, operations, elements, components, and/or groups thereof.

Unless otherwise defined herein, all terms used herein including technical or scientific terms have the same meanings as those generally understood by one of ordinary skill in the art. Terms defined in dictionaries generally used should be construed to have meanings matching contextual meanings in the related art and are not to be construed as an ideal or excessively formal meaning unless otherwise defined herein.

Hereinafter, example embodiments will be described in detail with reference to the accompanying drawings. The scope of the right, however, should not be construed as limited to the example embodiments set forth herein. Like reference numerals in the drawings refer to like elements throughout the present disclosure.

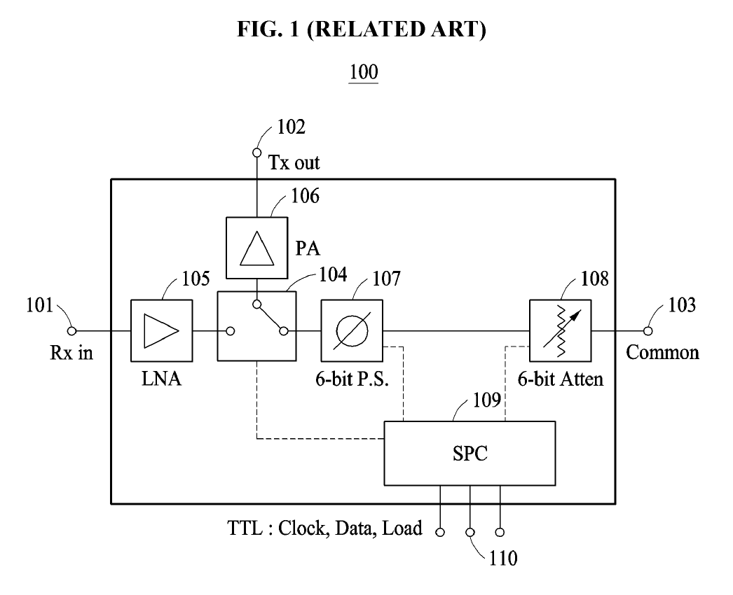

FIG. 1 is a diagram illustrating a structure of a multi-function monolithic microwave integrated circuit (MIMIC) 100 according to a related art.

Referring to FIG. 1, the multi-function MMIC 100 may operate in a reception (Rx) mode and a transmission (Tx) mode. The multi-function MMIC 100 may include an Rx input port 101, a Tx output port 102, a common port 103, a 3-port switch 104, a low noise amplifier (LNA) 105, a power amplifier (PA) 106, a digital phase shifter 107, a digital attenuator 108, and a serial-to-parallel converter (SPC) 109.

Since the digital phase shifter 107 and the digital attenuator 108 that are passive circuits are located in the multi-function MMIC 100, the multi-function MMIC 100 may have a structure that enables signals to bidirectionally move. However, due to the structure of the multi-function MIMIC 100, a noise factor in the Rx mode and an output power characteristic in the Tx mode may decrease.

The multi-function MIMIC 100 may include three radio frequency (RF) ports, for example, the Rx input port 101, the Tx output port 102 and the common port 103 that is used for an RX output and a Tx input. The Rx mode and the Tx mode of the multi-function MMIC 100 may be determined by the 3-port switch 104 connected to an input terminal of each of the digital phase shifter 107 and the digital attenuator 108.

In an example, when the 3-port switch 104 connects the LNA 105 to the digital phase shifter 107, the multi-function MMIC 100 may operate in the Rx mode. In this example, the common port 103 may operate as an output port in the Rx mode. In another example, when the 3-port switch 104 connects the PA 106 to the digital phase shifter 107, the multi-function MIMIC 100 may operate in the Tx mode. In this example, the common port 103 may operate as an input port in the Tx mode.

The SPC 109 may control the 3-port switch 104, the digital phase shifter 107 and the digital attenuator 108 for the Rx mode and/or the Tx mode.

An input 110 of the SPC 109 may include a clock, data and a load. Based on serial data synchronized with the clock, a switch control signal and signals to control the digital phase shifter 107 and the digital attenuator 108 may be input. For example, control signals or data may be input in series, may be synchronized with the clock, may be arranged and stored in parallel.

The stored control signals may be output in parallel by a load signal, to control the 3-port switch 104, the digital phase shifter 107 and the digital attenuator 108. For example, in response to a load signal that is an enabling signal being received, the control signals or data may be output in parallel. In response to the control signals being output in parallel, the 3-port switch 104, the digital phase shifter 107 and the digital attenuator 108 may be controlled.

In the structure of FIG. 1, since the digital phase shifter 107 and the digital attenuator 108 are passive circuits, a signal loss may occur. Due to the signal loss, the noise factor in the Rx mode and the output power characteristic in the Tx mode may deteriorate.

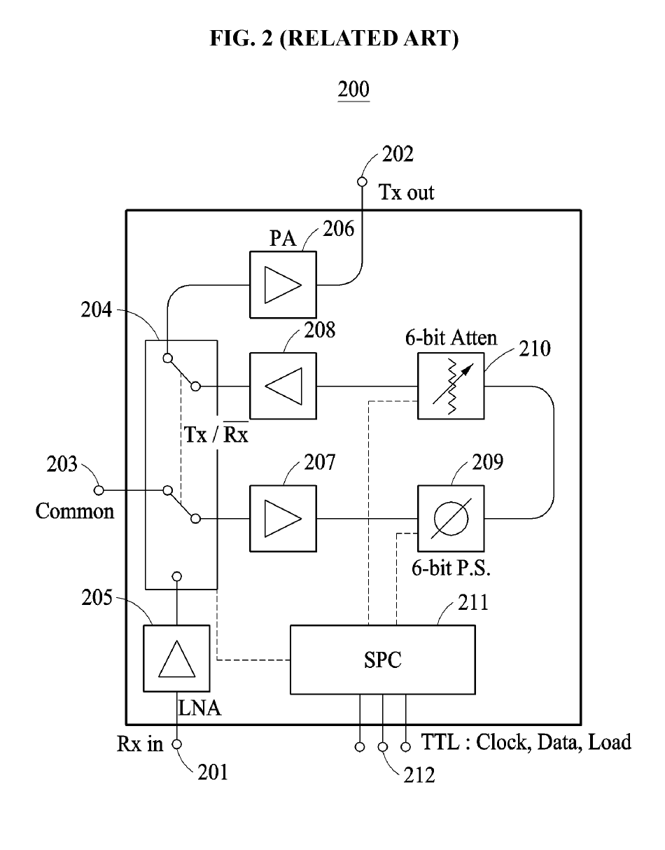

FIG. 2 is a diagram illustrating a structure of a multi-function MIMIC 200 according to a related art.

Referring to FIG. 2, the multi-function MMIC 200 may operate in an Rx mode and a Tx mode. The multi-function MIMIC 200 may include an Rx input port 201, a Tx output port 202, a common port 203, a 5-port switch 204, an LNA 205, a PA 206, an input amplifier 207, an output amplifier 208, a digital phase shifter 209, a digital attenuator 210, and an SPC 211.

To improve the noise factor in the Rx mode and the output power characteristic in the Tx mode that are deteriorated due to the structure of FIG. 1, the input amplifier 207 and the output amplifier 208 may be added to an input of the digital phase shifter 209 and an output of the digital attenuator 210 in the multi-function MMIC 200.

An appropriate path of an output of the LNA 205, an input of the PA 206, an input of the input amplifier 207, an output of the output amplifier 208 and the common port 203 may be determined by the 5-port switch 204, so that the multi-function MMIC 200 may operate in the Rx mode and the Tx mode.

The multi-function MIMIC 200 may include three RF ports, for example, the Rx input port 201, the Tx output port 202, and the common port 203 that is used for an RX output and a Tx input. The Rx mode and the Tx mode of the multi-function MMIC 200 may be determined by the 5-port switch 204.

In an example, when the 5-port switch 204 connects the output of the LNA 205 to the input of the input amplifier 207, the multi-function MMIC 200 may operate in the Rx mode. In this example, the common port 203 may be connected to the output of the output amplifier 208 and may operate as an output port in the Rx mode.

In another example, when the 5-port switch 204 connects the input of the PA 206 to the output of the output amplifier 208, the multi-function MMIC 200 may operate in the Tx mode. In this example, the common port 203 may be connected to the input of the input amplifier 207 and may operate as an input port in the Tx mode.

The input amplifier 207 may function to improve a noise factor characteristic in the Rx mode, and the output amplifier 208 may function to improve an output power characteristic in the Tx mode. Since the input amplifier 207 and the output amplifier 208 are active circuits, a signal may move in one direction. Thus, the multi-function MIMIC 200 may require the 5-port switch 204, and the 5-port switch 204 may be located in the input of the input amplifier 207 and the output of the output amplifier 208.

The digital phase shifter 209 and the digital attenuator 210 may be passive circuits such as circuits of FIG. 1.

The SPC 211 may control the 5-port switch 204, the digital phase shifter 209 and the digital attenuator 210 to determine the Rx mode and/or the Tx mode. An input interface of the SPC 211 may be the same as that of FIG. 1.

An input 212 of the SPC 211 may include a clock, data and a load. Based on serial data synchronized with the clock, a switch control signal and signals to control the digital phase shifter 209 and the digital attenuator 210 may be input. For example, control signals or data may be input in series, may be synchronized with the clock, may be arranged and stored in parallel.

The stored control signals may be output in parallel by a load signal, to control the 5-port switch 204, the digital phase shifter 209 and the digital attenuator 210. For example, in response to a load signal that is an enabling signal being received, the control signals or data may be output in parallel. In response to the control signals being output in parallel, the S-port switch 204, the digital phase shifter 209 and the digital attenuator 210 may be controlled.

In the structure of FIG. 2, the multi-function MMIC 200, that is, an entire circuit may operate only when both the input amplifier 207 and the output amplifier 208 that are in the same path are turned on in the Rx mode and the Tx mode. Thus, a direct current (DC) power consumption by the input amplifier 207 and the output amplifier 208 may increase.

Also, since the input of the input amplifier 207 and the output of the output amplifier 208 are located close to each other in the structure of FIG. 2, a possibility of a loop resonance may exist. Due to the loop resonance, a signal may be distorted, and a loop oscillation of the entire circuit, that is, the multi-function MMIC 200 may occur in response to a severe loop resonance.

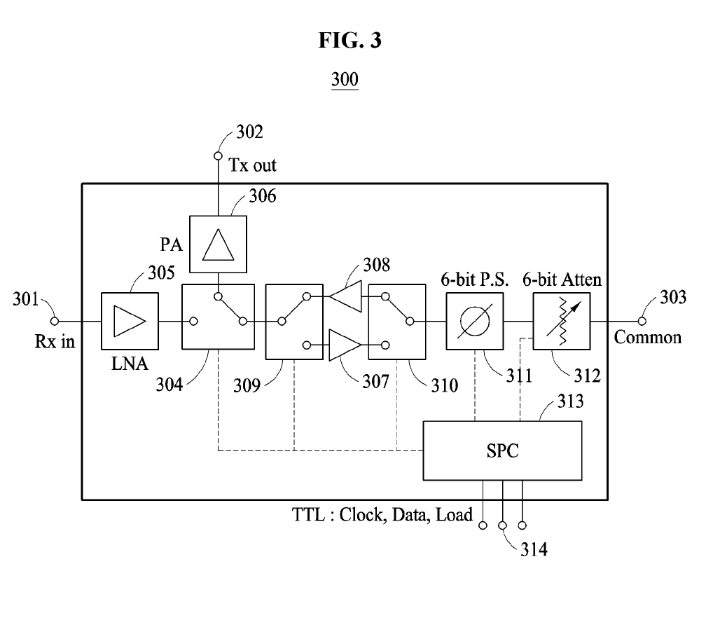

FIG. 3 is a diagram illustrating a structure of a multi-function MIMIC 300 according to an example embodiment.

Referring to FIG. 3, the multi-function MMIC 300 may include an Rx input port 301, a Tx output port 302, a common port 303, 3-port switches 304, 309 and 310, an LNA 305, a PA 306, an input amplifier 307, an output amplifier 308, a digital phase shifter 311, a digital attenuator 312, and an SPC 313.

The multi-function MIMIC 300 may operate in an Rx mode and a Tx mode and may improve a noise factor in the Rx mode and an output power characteristic in the Tx mode. Also, in the structure of the multi-function MMIC 300 in which disadvantages of FIG. 2 are improved, the input amplifier 307 and the output amplifier 308 may be located in opposite directions in input terminals of the digital phase shifter 311 and the digital attenuator 312, and the 3-port switches 309 and 310 may be connected to an input and an output of each of the input amplifier 307 and the output amplifier 308. Also, the multi-function MMIC 300 may allow one of the input amplifier 307 and the output amplifier 308 to be turned on for each mode, that is, the Rx mode or the Tx mode. Thus, a DC power consumption by the multi-function MMIC 300 may be relatively reduced, and a loop of FIG. 2 may not be formed, and accordingly a possibility of a loop resonance may not exist.

In the multi-function MIMIC 300, the LNA 305 may be located in an input of the Rx mode and the PA 306 may be located in an output of the Tx mode, similarly to the structures of FIGS. 1 and 2. Also, in the multi-function MMIC 300, the input amplifier 307 and the output amplifier 308 may be located in opposite directions in input terminals of the digital phase shifter 311 and the digital attenuator 312, and the 3-port switches 309 and 310 may be located in an input and an output of each of the input amplifier 307 and the output amplifier 308. The digital phase shifter 311 and the digital attenuator 312 may be passive circuits.

For example, the input amplifier 307 may be a first amplifier that includes a first input terminal and a first output terminal, and the output amplifier 308 may be a second amplifier that includes a second input terminal and a second output terminal. The 3-port switch 309 may be a first switch that is connectable to the first input terminal and the second output terminal, and the 3-port switch 310 may be a second switch that is connectable to the first output terminal and the second input terminal. The first switch and the second switch may be 3-port switches. Also, the first switch and the second switch may be arranged in parallel in opposite directions and may be located between the first switch and the second switch.

The multi-function MIMIC 300 may include three RF ports, for example, the Rx input port 301, the Tx output port 302 and the common port 303, similarly to the structure of FIG. 2. The Rx mode and the Tx mode of the multi-function MMIC 300 may be determined by the 3-port switch 304.

In an example, when the 3-port switch 304 connects the LNA 305 to the input amplifier 307, the multi-function MMIC 300 may operate in the Rx mode. In this example, the common port 303 may operate as an output port in the Rx mode.

In another example, when the 3-port switch 304 connects the PA 306 to the output amplifier 308, the multi-function MMIC 300 may operate in the Tx mode. In this example, the common port 303 may operate as an input port in the Tx mode.

The SPC 313 may control the multi-function MMIC 300, that is, the 3-port switches 304, 309 and 310, the digital phase shifter 311 and the digital attenuator 312. An input interface of the SPC 313 may be the same as that of FIG. 1.

An input 314 of the SPC 313 may include a clock, data and a load. Based on serial data synchronized with the clock, a switch control signal and signals to control the digital phase shifter 311 and the digital attenuator 312 may be input. For example, control signals or data may be input in series, may be synchronized with the clock, may be arranged and stored in parallel.

The stored control signals may be output in parallel by a load signal, to control the 3-port switches 304, 309 and 310, the digital phase shifter 311 and the digital attenuator 312. For example, in response to a load signal that is an enabling signal being received, the control signals or data may be output in parallel. In response to the control signals being output in parallel, the 3-port switches 304, 309 and 310, the digital phase shifter 311 and the digital attenuator 312 may be controlled.

A switch control signal of the SPC 313 may control the 3-port switch 304 that determines the Rx mode and/or the Tx mode to operate with the 3-port switches 309 and 310 connected to a front side and a rear side of each of the input amplifier 307 and the output amplifier 308.

For example, the SPC 313 may control a signal to be transmitted via one of the input amplifier 307 and the output amplifier 308, based on the switch control signal, in each of the Rx mode and the Tx mode of the multi-function MMIC 300.

The SPC 313 may control a DC bias to be prevented from being supplied to the other one of the input amplifier 307 and the output amplifier 308, in each of the Rx mode and the Tx mode.

The multi-function MMIC 300 may turn off an amplifier that is not in an operating mode between the input amplifier 307 and the output amplifier 308 that are turned on based on a control of the SPC 313. Since a DC power is not applied to the amplifier in an off state, an entire circuit, that is, the multi-function MMIC 300 may not be affected by the amplifier. In other words, since a DC power is not applied to one amplifier, a total amount of DC power to be consumed by the multi-function MMIC 300 may decrease. Also, a loop may not be formed in the multi-function MMIC 300, and accordingly a possibility of a loop resonance may not exist. Thus, the multi-function MMIC 300 may have a more stable structure without a possibility of a signal distortion or oscillation.

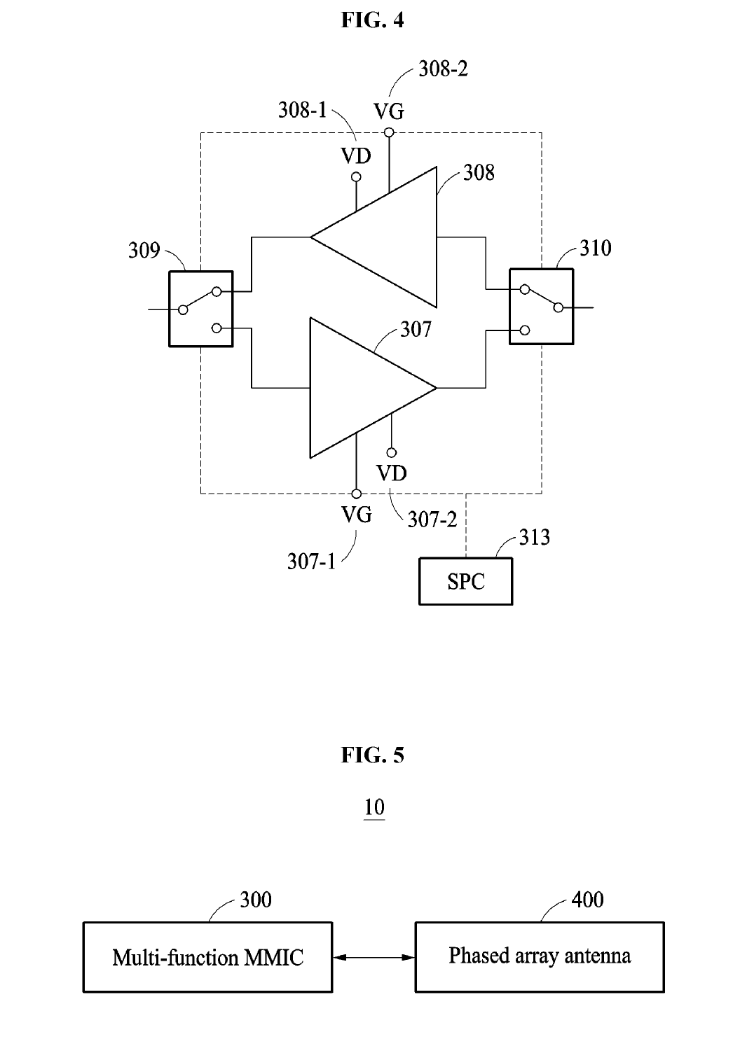

FIG. 4 is a diagram illustrating a circuit for an operation of switches located in front of and behind two amplifiers that are located in opposite directions.

Referring to FIG. 4, the input amplifier 307 and the output amplifier 308 may be located in opposite directions and the 3-port switches 309 and 310 may be connected to an input and an output of each of the input amplifier 307 and the output amplifier 308. The input amplifier 307 may be turned on in the Rx mode, and the output amplifier 308 may be turned on in the Tx mode.

For example, the input amplifier 307 may be turned on in the Rx mode and may be turned off in the Tx mode, based on the control of the SPC 313. The output amplifier 308 may be turned off in the Rx mode and may be turned on in the Tx mode, based on the control of the SPC 313.

In the Rx mode, the 3-port switches 309 and 310 may connect an input and an output of the input amplifier 307 to an external circuit. In the Tx mode, the 3-port switches 309 and 310 may connect an input and an output of the output amplifier 308 to the external circuit.

For example, the 3-port switches 309 and 310 may operate to connect a first input terminal and a first output terminal of the input amplifier 307 to an element of the multi-function MMIC 300 in the Rx mode based on the control of the SPC 313. The 3-port switches 309 and 310 may operate to connect a second input terminal and a second output terminal of the output amplifier 308 to the element of the multi-function MMIC 300 in the Tx mode based on the control of the SPC 313.

For operations of the input amplifier 307 and the output amplifier 308, the multi-function MMIC 300 may supply a DC bias. The DC bias may be supplied via gate voltages 307-1 and 308-2 and drain voltages 307-2 and 308-1.

The input amplifier 307 and the output amplifier 308 may be implemented as enhancement-mode high electron mobility transistor (E-HEMT)-based amplifiers.

In an E-HEMT-based amplifier, a gate voltage may need to have a positive value to allow a drain current to flow. When a gate voltage is 0 volts (V), the drain current may not flow in the E-HEMT-based amplifier.

The E-HEMT-based amplifier may be turned on or off based on the above HEMT characteristic.

For example, when positive values or 0 V are applied as the gate voltages 307-1 and 308-2 in interoperation with the 3-port switches 309 and 310, the input amplifier 307 and the output amplifier 308 may be turned on or off In this example, voltages with constant values may be applied as the drain voltages 307-2 and 308-1. The above structure may allow a single amplifier to operate in each of the Rx mode and the Tx mode, and thus it is possible to relatively reduce a power consumption.

FIG. 5 is a diagram illustrating a structure of a phased array antenna system 10 according to an example embodiment.

Referring to FIG. 5, the phased array antenna system 10 may include a multi-function MIMIC 300 for a phased array antenna system, and a phased array antenna 400.

The phased array antenna system 10 may be an active system or a passive system.

When the phased array antenna system 10 is an active system, a core chip of the phased array antenna system 10 may be the multi-function MMIC 300.

The multi-function MIMIC 300 of FIG. 5 may be the same as that of FIG. 3, and accordingly further description is not repeated herein.

However, the multi-function MIMIC 300 of FIG. 5 may be a multi-function chip or a core chip configured to control a phase and a magnitude of a signal or data of the phase array antenna 400.

The multi-function MIMIC 300 may be bonded to a multilayer integrated circuit (IC) package via a single solder ball or a plurality of solder balls.

The multi-function MIMIC 300 may receive a signal from the phase array antenna 400, or transmit a signal to the phase array antenna 400. For example, a signal transferred to the phase array antenna 400 may be a signal that has a shifted phase and that is amplified.

The phase array antenna 400 may transmit or receive a signal or data. For example, the phase array antenna 400 may transmit and receive a signal based on a control of the multi-function MMIC 300.

The phase array antenna 400 may include a plurality of antenna elements. For example, each of the plurality of antenna elements may include an interconnection for communicatively coupling to an associated transmitter and/or receiver, a feeder line, a quarter wavelength transformer, and a radiating portion (for example, a folded dipole). The plurality of antenna elements may each have a metallic or conductive structure coupled to a transceiver.

The components described in the example embodiments may be implemented by hardware components including, for example, at least one digital signal processor (DSP), a processor, a controller, an application-specific integrated circuit (ASIC), a programmable logic element, such as a field programmable gate array (FPGA), other electronic devices, or combinations thereof. At least some of the functions or the processes described in the example embodiments may be implemented by software, and the software may be recorded on a recording medium. The components, the functions, and the processes described in the example embodiments may be implemented by a combination of hardware and software.

The apparatuses, and other components described herein may be implemented using a hardware component, a software component and/or a combination thereof. A processing device may be implemented using one or more general-purpose or special purpose computers, such as, for example, a processor, a controller and an arithmetic logic unit (ALU), a DSP, a microcomputer, an FPGA, a programmable logic unit (PLU), a microprocessor or any other device capable of responding to and executing instructions in a defined manner. The processing device may run an operating system (OS) and one or more software applications that run on the OS. The processing device also may access, store, manipulate, process, and create data in response to execution of the software. For purpose of simplicity, the description of a processing device is used as singular; however, one skilled in the art will appreciated that a processing device may include multiple processing elements and multiple types of processing elements. For example, a processing device may include multiple processors or a processor and a controller. In addition, different processing configurations are possible, such a parallel processors.

The software may include a computer program, a piece of code, an instruction, or some combination thereof, to independently or collectively instruct or configure the processing device to operate as desired. Software and data may be embodied permanently or temporarily in any type of machine, component, physical or virtual equipment, computer storage medium or device, or in a propagated signal wave capable of providing instructions or data to or being interpreted by the processing device. The software also may be distributed over network coupled computer systems so that the software is stored and executed in a distributed fashion. The software and data may be stored by one or more non-transitory computer readable recording mediums.

The methods according to the above-described example embodiments may be recorded in non-transitory computer-readable media including program instructions to implement various operations of the above-described example embodiments. The media may also include, alone or in combination with the program instructions, data files, data structures, and the like. The program instructions recorded on the media may be those specially designed and constructed for the purposes of example embodiments, or they may be of the kind well-known and available to those having skill in the computer software arts. Examples of non-transitory computer-readable media include magnetic media such as hard disks, floppy disks, and magnetic tape; optical media such as CD-ROM discs, DVDs, and/or Blue-ray discs; magneto-optical media such as optical discs; and hardware devices that are specially configured to store and perform program instructions, such as read-only memory (ROM), random access memory (RAM), flash memory (e.g., USB flash drives, memory cards, memory sticks, etc.), and the like. Examples of program instructions include both machine code, such as produced by a compiler, and files containing higher level code that may be executed by the computer using an interpreter. The above-described devices may be configured to act as one or more software modules in order to perform the operations of the above-described example embodiments, or vice versa.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

1. A monolithic microwave integrated circuit (MMIC) for a phased array antenna system, the MMIC having a reception (Rx) mode and a transmission mode (Tx) mode and comprising:
a low noise amplifier coupled to a Rx input port;
a power amplifier coupled to a Tx output port;
a first amplifier comprising a first input terminal and a first output terminal;
a second amplifier comprising a second input terminal and a second output terminal;
a first switch connectable to the first input terminal and the second output terminal; and
a second switch connectable to the first output terminal and the second input terminal,
wherein the first amplifier and the second amplifier are arranged in parallel in opposite directions and are located between the first switch and the second switch,
wherein the first amplifier is connected to the low noise amplifier in the Rx mode, and the second amplifier is connected to the power amplifier in the Tx mode.

2. The MMIC of claim 1, further comprising:
a serial-to-parallel converter (SPC) configured to control the MMIC,
wherein the SPC is configured to control a signal to be transmitted through one of the first amplifier and the second amplifier in each of the Rx mode and Tx mode of the MMIC.

3. The MMIC of claim 2, wherein the SPC is configured to control a direct current (DC) bias to be prevented from being supplied to the other one of the first amplifier and the second amplifier in each of the Rx mode and the Tx mode.

4. The MMIC of claim 2, wherein
the first switch and the second switch operate to connect the first input terminal and the first output terminal to an element of the MMIC in the Rx mode, and
the first switch and the second switch operate to connect the second input terminal and the second output terminal to the element of the MMIC in the Tx mode.

5. The MMIC of claim 4, wherein
the first amplifier is turned on in the Rx mode and turned off in the Tx mode, and
the second amplifier is turned off in the Rx mode and turned on in the Tx mode.

6. The MMIC of claim 5, wherein the first amplifier and the second amplifier are implemented as enhancement-mode high electron mobility transistor (E-HEMT)-based amplifiers.

7. A phased array antenna system comprising:
a phased array antenna; and
a monolithic microwave integrated circuit (MMIC) configured to control the phased array antenna,
wherein the MMIC having a reception (Rx) mode and a transmission mode (Tx) mode and comprises:
a low noise amplifier coupled to a Rx input port;
a power amplifier coupled to a Tx output port;
a first amplifier comprising a first input terminal and a first output terminal;
a second amplifier comprising a second input terminal and a second output terminal;
a first switch connectable to the first input terminal and the second output terminal; and
a second switch connectable to the first output terminal and the second input terminal,
wherein the first amplifier and the second amplifier are arranged in parallel in opposite directions and are located between the first switch and the second switch, and
wherein the first amplifier is connected to the low noise amplifier in the Rx mode, and the second amplifier is connected to the power amplifier in the Tx mode.

8. The phased array antenna system of claim 7, wherein
the MMIC further comprises a serial-to-parallel converter (SPC) configured to control the MMIC, and
the SPC is configured to control a signal to be transmitted through one of the first amplifier and the second amplifier in each of the Rx mode and a transmission Tx mode of the MMIC.

9. The phased array antenna system of claim 8, wherein the SPC is configured to control a direct current (DC) bias to be prevented from being supplied to the other one of the first amplifier and the second amplifier in each of the Rx mode and the Tx mode.

10. The phased array antenna system of claim 8, wherein
the first switch and the second switch operate to connect the first input terminal and the first output terminal to an element of the MMIC in the Rx mode, and
the first switch and the second switch operate to connect the second input terminal and the second output terminal to the element of the MMIC in the Tx mode.

11. The phased array antenna system of claim 10, wherein
the first amplifier is turned on in the Rx mode and turned off in the Tx mode, and
the second amplifier is turned off in the Rx mode and turned on in the Tx mode.

12. The phased array antenna system of claim 11, wherein the first amplifier and the second amplifier are implemented as enhancement-mode high electron mobility transistor (E-HEMT)-based amplifiers.
